(19) United States
(12) Patent Application Publication
(10) Pub. No.: US 2024/0306475 A1
(43) Pub. Date: Sep. 12, 2024

(54) DISPLAY DEVICE AND METHOD FOR MANUFACTURING THE SAME

(71) Applicant: Samsung Display Co., LTD., Yongin-si (KR)

(72) Inventors: CHANGYEONG SONG, Yongin-si (KR); YEONGUK KIM, Yongin-si (KR); HEEYEON PARK, Yongin-si (KR); JAEHEUNG HA, Yongin-si (KR); JONGWOO KIM, Yongin-si (KR); SOYOUNG OH, Yongin-si (KR); HYUNSUP YOON, Yongin-si (KR); WOOSUK JUNG, Yongin-si (KR)

(21) Appl. No.: 18/583,129

(22) Filed: Feb. 21, 2024

(30) Foreign Application Priority Data
Mar. 2, 2023 (KR) 10-2023-0027795

(51) Int. Cl. H10K 59/80; C09B 23/01; C09B 23/10; H10K 59/12

(52) U.S. Cl. CPC H10K 59/873; C09B 23/0066; C09B 23/105; C09B 23/107; H10K 59/1201; H10K 59/8792

(57) ABSTRACT

Provided are a display device and a method for manufacturing the same. The display device of an embodiment may include a base layer, a light emitting element, and an encapsulation layer. The encapsulation layer included in the display device may include a first inorganic layer, a second inorganic layer, and an organic layer, and the organic layer may include a near-infrared absorbing dye to contribute to reducing a dead space, and accordingly, the display device may exhibit improved display quality.

### CROSS-REFERENCE TO RELATED APPLICATION

This application claims priority to and the benefit of Korean Patent Application No. 10-2023-0027795, filed on Mar. 2, 2023, the entire contents of which are hereby incorporated by reference.

### BACKGROUND

### 1. Field

Embodiments of the present disclosure herein relate to a display device and a method for manufacturing the same, and, for example, to a display device having improved reliability and also minimized or reduced dead space, and a method for manufacturing the same.

### DESCRIPTION OF THE RELATED ART

Various types (or kinds) of display devices are used to provide image information. The display devices may include display panels for displaying images. An emission layer of an organic light emitting display device among the display devices may include organic matter. In order to protect the organic matter susceptible to oxygen and moisture, various technologies for sealing organic light emitting elements have been developed.

Recently, a structure of a flexible display device in which a non-display region is minimized or reduced, or a non-display region is bent has been suggested to improve viewability and reduce a dead space. A process design for a display device capable of providing suitable satisfactory quality even when the dead space is reduced is required or desired.

### SUMMARY

Embodiments of the present disclosure provide a display device having improved reliability and display quality, and a method for manufacturing the display device.

An embodiment of the present disclosure provides a display device including a base layer including a display region and a non-display region adjacent to the display region, a light emitting element on the base layer and overlapping the display region. The encapsulation layer may include a first inorganic layer overlapping the display region and the non-display region, a second inorganic layer on the first inorganic layer, and an organic layer between the first inorganic layer and the second inorganic layer and including a near-infrared absorbing dye.

In an embodiment, the organic layer may include the near-infrared absorbing dye in an amount in a range of greater than about 0 wt % to about 5 wt % or less.

In an embodiment, the organic layer may have a visible light transmittance of about 97% or greater. In an embodiment, the organic layer has a thickness of about 0.3 μm to about 20 μm.

In an embodiment, the near-infrared absorbing dye may include at least one selected from the compounds of Compound Group 1, which will be further described herein below.

In an embodiment, the organic layer may be formed from a resin composition including the near-infrared absorbing dye and a base resin. In an embodiment, the base resin may include at least one selected from an acryl-based resin, an epoxy-based resin, and a silicone-based resin.

In an embodiment, the display device may further include a pixel defining film on the base layer and having a pixel opening and a recess portion defined therein. The pixel opening may overlap the display region and the recess portion may overlap the non-display region, and the first inorganic layer may be provided along a step between the pixel opening and the recess portion. In an embodiment, the organic layer may fill the pixel opening and the recess portion on the first inorganic layer.

In an embodiment, the display device may further include a dam portion overlapping the non-display region and spaced apart from the light emitting element and on the base layer. In an embodiment, the first inorganic layer may cover the dam portion, and the organic layer may extend to the dam portion and be on one side of the dam portion adjacent to the display region on a cross section perpendicular (or substantially perpendicular) to the base layer.

In an embodiment of the present disclosure, a display device includes a display element layer including a light emitting element, an encapsulation layer on the display element layer and including a base resin and a near-infrared absorbing dye, and a sensor layer on the encapsulation layer.

In an embodiment of the present disclosure, a method for manufacturing a display device includes forming a display element layer including a light emitting element on the base layer, and forming an encapsulation layer on the display element layer. The forming of the encapsulation layer may include forming a first inorganic layer on the display element layer, providing a resin composition including a near-infrared absorbing dye on the first inorganic layer to form an organic layer, identifying an edge of the organic layer, and forming a second inorganic layer on the organic layer.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view showing a display device according to an embodiment of the present disclosure;

FIG. 2 is an exploded perspective view of a display device according to an embodiment of the present disclosure;

FIG. 3 is a cross-sectional view of a display device according to an embodiment of the present disclosure;

FIG. 4 is a plan view of a display panel according to an embodiment of the present disclosure;

FIGS. 5A-5B are each a cross-sectional view of some components of a display device according to an embodiment of the present disclosure;

FIG. 6 is a flowchart showing each step in a method for manufacturing a display device according to an embodiment of the present disclosure;

FIG. 7 is a flowchart showing some steps in a method for manufacturing a display device according to an embodiment of the present disclosure; and

FIGS. 8A-8E are cross-sectional views sequentially showing some steps in a method for manufacturing a display device according to an embodiment of the present disclosure.

### DETAILED DESCRIPTION

The subject matter of the present disclosure may be modified in many alternate forms, and thus example embodiments will be illustrated in the drawings and described herein in more detail. It should be understood, however, that it is not intended to limit the present disclosure to the particular forms disclosed, but rather, is intended to cover all modifications, equivalents, and alternatives falling within the spirit and scope of the present disclosure.

It will be understood that when an element (or a region, a layer, a portion, or the like) is referred to as “being on”, “connected to” or “coupled to” another element, it may be directly on, connected or coupled to the other element, or intervening elements may be therebetween.

Like reference numerals refer to like elements. In addition, in the drawings, the thickness, the ratio, and the dimensions of elements may be exaggerated for an effective description of technical contents. The term “and/or,” includes all combinations of one or more of which associated configurations may define.

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the spirit and scope of the present disclosure. The singular forms are intended to include the plural forms as well, unless the context clearly indicates otherwise.

Also, terms of “below”, “on lower side”, “above”, “on upper side”, or the like may be used to describe the relationships of the components shown in the drawings. The terms are used as a relative concept and are described with reference to the direction indicated in the drawings.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure pertains. It is also to be understood that terms defined in commonly used dictionaries should be interpreted as having meanings consistent with the meanings in the context of the related art, and are expressly defined herein unless they are interpreted in an ideal or overly formal sense. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, a display device according to an embodiment of the present disclosure and a method for manufacturing a display device will be described with reference to the accompanying drawings.

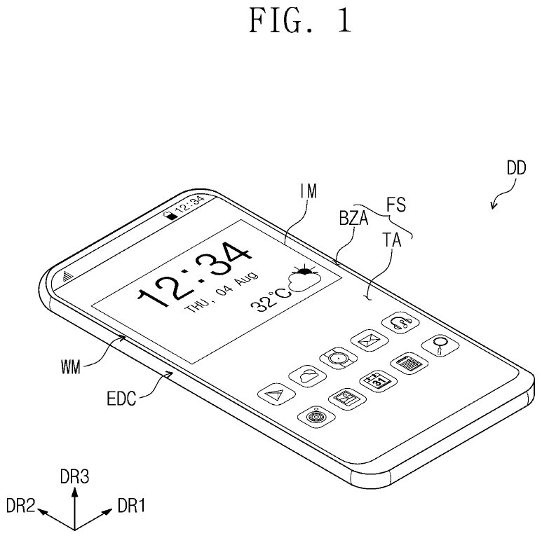

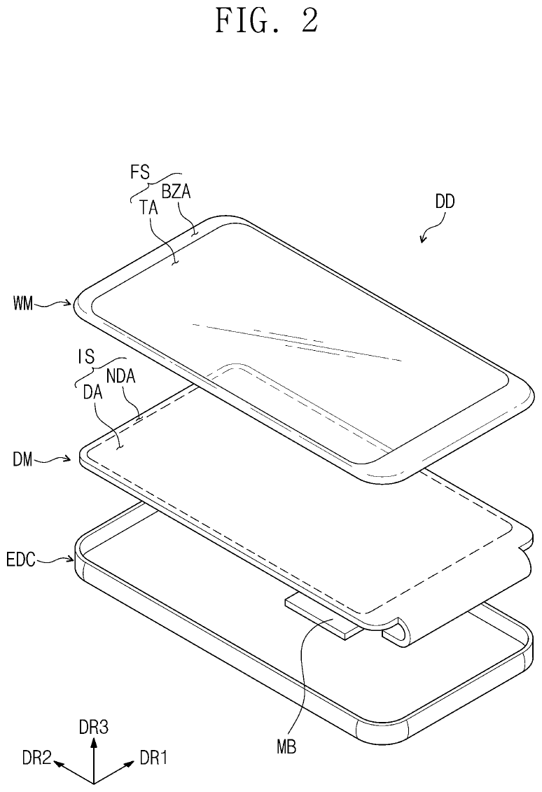

FIG. 1 is a perspective view showing a display device DD according to an embodiment of the present disclosure. FIG. 2 is an exploded perspective view of a display device DD according to an embodiment of the present disclosure.

The display device DD may be a device activated according to electrical signals and display images. The display device DD may display an image IM and sense external inputs. For example, the display device DD may not only include large-sized devices such as a television set and an outdoor billboard, but also include small- and medium-sized devices such as a monitor, a mobile phone, a tablet computer, a computer, a navigation system, and a game console. Embodiments of the display device DD are examples, and thus are not limited to any particular one without departing from the spirit and scope of present disclosure. In the present embodiment, a mobile phone is shown as an example of the display device DD.

Referring to FIG. 1, the display device DD may have short sides in a first direction DR1 and long sides in a second direction DR2 crossing the first direction DR1 when viewed on a plane. However, the embodiment of the present disclosure is not limited thereto, and the display device DD may have various suitable shapes such as a circular shape and a polygonal shape.

The display device DD of an embodiment may be flexible. The term “flexible” indicates a property of being bendable, and may include all from a structure being completely foldable to a structure being bendable up to several nanometers. For example, the flexible display device DD may include a curved device and/or a foldable device. However, the embodiment of the present disclosure is not limited thereto, and the display device DD may be rigid.

The display device DD may display, in a third direction DR3, the image IM on a display surface parallel (or substantially parallel) to each of the first direction DR1 and the second direction DR2. The image IM provided in the display device DD may include still images as well as dynamic images. In FIG. 1, a watch window and icons are shown as an example of the image IM.

A display surface on which the image IM is displayed may correspond to a front surface of the display device DD and also may correspond to a front surface FS of a window WP. FIG. 1 shows a flat display surface as an example, but the embodiment of the present disclosure is not limited thereto, and the display surface of the display device DD may further include a curved surface bent from at least one side of a plane.

In the present embodiment, a front surface (or an upper surface) and a rear surface (or a lower surface) of respective members are defined with respect to a direction in which the image IM is displayed. The front and rear surfaces of each member constituting the display device DD may oppose each other in the third direction DR3 and a normal direction of each of the front and rear surfaces may substantially be parallel (or substantially parallel) to the third direction DR3. The distance between the front surface and the rear surface defined along the third direction DR3 may correspond to a thickness of a member (or a unit). Directions indicated by the first to third directions DR1, DR2, and DR3 are relative concepts, and may thus be changed to other directions.

The display device DD according to an embodiment of the present disclosure may sense user inputs applied from the outside. For example, the user inputs include various suitable types (or kinds) of external inputs such as a portion of the user's body, light, heat, and/or pressure. The display device DD may also sense the user inputs applied to a side surface or a rear surface of the display device DD depending on a structure of the display device DD, and is not limited to one embodiment.

Referring to FIGS. 1-2, the display device DD may include a window WM, a display module DM, and a case EDC. The window WM may be bonded to the case EDC to form an outer portion of the display device DD, and may provide an inner space for housing components of the display device DD. In the present embodiment, the case EDC, the display module DM, and the window WM may be sequentially stacked along the third direction DR3.

The window WM may be on the display module DM. The window WM may have a shape corresponding to the shape of the display module DM. The window WM may cover an entire outer side of the display module DM and may protect the display module DM from external shocks and scratches.

The window WM may include an optically transparent insulating material. For example, the window WM may include a glass substrate and/or a polymer substrate. The window WM may have a single layer structure or a multilayer structure. For example, the window WM may be a tempered glass substrate subjected to a strengthening treatment. In some embodiments, the window WM may be formed of polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof. However, this is presented as an example, and the material included in the window WM is not limited thereto.

In some embodiments, the window WM may further include at least one functional layer provided on a transparent substrate. For example, the functional layer may be an anti-fingerprint layer, a phase control layer, a hard coating layer, and/or the like, but the embodiment of the present disclosure is not limited thereto.

The front surface FS of the window WM may include a transmission region TA and a bezel region BZA. The transmission region TA of the window WM may be an optically transparent region. For example, the transmission region TA may be a region having a visible light transmittance of about 90% or greater.

The window WM may transmit the image IM provided from the display panel DP through the transmission region TA, and users may view the corresponding image IM.

The bezel region BZA of the window WM may be provided as a region on which a material including a set or predetermined color is printed. The bezel region BZA of the window WM may prevent a configuration of the display module DM overlapping the bezel region BZA from being viewed from the outside (or may reduce visibility thereof from the outside).

The bezel region BZA may be positioned adjacent to the transmission region TA. The shape of the transmission region TA may be substantially defined by the bezel region BZA. For example, the bezel region BZA may be outside the transmission region TA to surround the transmission region TA. However, this is presented as an example, and the bezel region BZA may be positioned adjacent to only one side of the transmission region TA or may be omitted. In addition, the bezel region BZA may be on an inner surface of the display device DD instead of the front surface thereof.

The display module DM may be between the window WM and the case EDC. The display module DM may display the image IM in response to electrical signals and sense external inputs. The image IM may be displayed on the front surface IS of the display module DM. The front surface IS of the display module DM may include a display region DA and a non-display region NDA. The display region DA may be a region activated according to electrical signals and displaying image IM. According to an embodiment, the display region DA of the display panel DP may correspond to the transmission region TA of the window WM.

As used herein, “a region/portion corresponds to another region/portion” indicates that “the regions/portions overlap each other”, and is not limited to having the same surface area and/or having the same shape.

The non-display region NDA may be adjacent to the outside of the display region DA. For example, the non-display region NDA may surround the display region DA. However, the embodiment of the present disclosure is not limited thereto, and the non-display region NDA may be defined in various suitable shapes.

The non-display region NDA may be a region in which a driving circuit and/or driving wiring for driving elements in the display region DA, various suitable signal lines for providing electric signals, and pads may be provided. The non-display region NDA of the display module DM may correspond to the bezel region BZA of the window WM. The bezel region BZA may prevent components of the display module DM in the non-display region NDA from being viewed from the outside (or may reduce visibility thereof from the outside).

The display device DD may include a circuit board MB connected to the display module DM. The circuit board MB may be bonded to one side of the display module DM extending in the second direction DR2 to be physically and electrically connected to the display module DM. The circuit board MB may generate electrical signals provided to the display module DM. For example, the circuit board MB may include a timing controller configured to generate signals provided to a driving unit of the display module DM in response to control signals received from the outside.

As an example of the present disclosure, at least a portion of the display module DM may be bent. For example, a portion of the display module DM to which the circuit board MB is connected may be bent, so that the circuit board MB faces the rear surface of the display module DM. The circuit board MB may be provided and assembled so as to overlap the rear surface of the display module DM when viewed on a plane. However, the embodiment of the present disclosure is not limited thereto, and the display module DM and the circuit board MB may be connected through flexible circuit boards each connected to one end of the display module DM and the circuit board MB.

The case EDC may be below the display module DM to house the display module DM. The case EDC may include a glass, plastic, and/or metal material having a relatively high rigidity, and/or a plurality of frames and/or plates formed of combinations thereof. The case EDC absorbs shocks applied from the outside and/or prevents or reduces penetration of foreign substances/moisture into the display module DM, and may thus protect the display module DM.

In addition, the display device DD may further include an electronic module including various suitable functional modules for operating the display module DM, and a power supply module that supplies power for the display device DD. For example, the display device DD may include a camera module as an example of the electronic module.

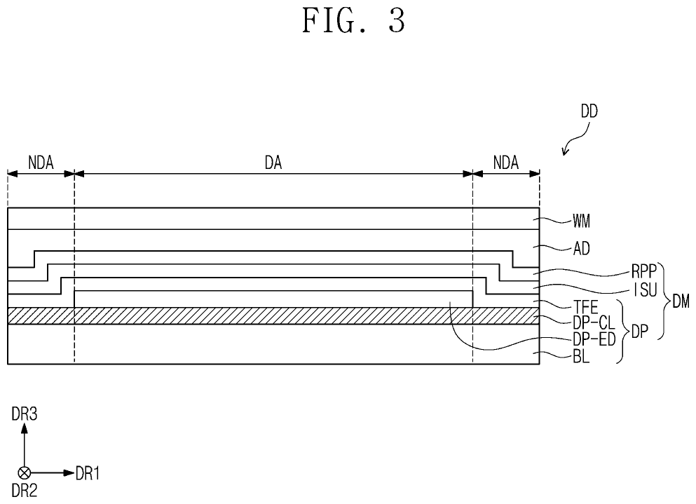

FIG. 3 is a cross-sectional view of the display device DD according to an embodiment of the present disclosure. Referring to FIG. 3, the display device DD may include a display module DM and a window WM, and the display module DM may include a display panel DP, an input sensing layer ISU, and an anti-reflector RPP.

The display panel DP may be a component for substantially generating the image IM (FIG. 1). The display panel DP may be a light emitting display panel. For example, the display panel DP may be an organic light emitting display panel, an inorganic light emitting display panel, a quantum dot display panel, a micro LED display panel, and/or a nano LED display panel. The display panel DP may be referred to as a display layer. The display panel DP may include a base layer BL, a circuit layer DP-CL, a display element layer DP-ED, and an encapsulation layer TFE.

The base layer BL may include a display region DA and a non-display region NDA. The base layer BL may be a member providing a base surface in which the circuit layer DP-CL is provided. The base layer BL may be a rigid substrate, and/or a flexible substrate that is bendable, foldable, rollable, and/or the like.

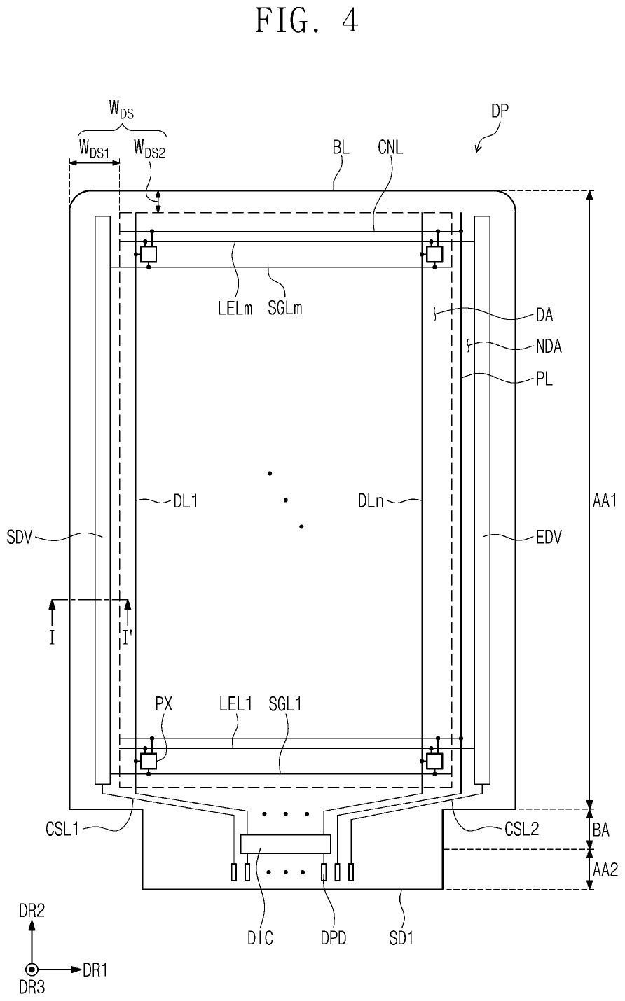

The circuit layer DP-CL may be on the base layer BL. The circuit layer DP-CL may include at least one insulating layer, a semiconductor pattern, a conductive pattern, signal lines, and/or the like. In addition, the circuit layer DP-CL may include driving circuits of a pixel PX (FIG. 4), which will be further described herein below.

The display element layer DP-ED may be on the circuit layer DP-CL. The display element layer DP-ED may include light emitting elements overlapping the display region DA. The light emitting elements of the display element layer DP-ED may be electrically connected to driving elements of the circuit layer DP-CL, and may thus provide source light through the display region DA according to signals from the driving elements. In an embodiment, the source light may be blue light, but the embodiment of the present disclosure is not limited thereto.

The encapsulation layer TFE may be on the display element layer DP-ED. The encapsulation layer TFE may serve to protect the display element layer DP-ED from moisture, oxygen, and foreign substances such as dust particles. The encapsulation layer TFE may include at least one inorganic layer and at least one organic layer.

The input sensing layer ISU may be formed on the display panel DP through a roll-to-roll process. In this case, the input sensing layer ISU may be directly on the display panel DP. As used herein, “a component B is directly/directly formed on a component A” indicates that a third component is not between the component A and the component B. Therefore, a component B is “directly/directly formed” on a component A indicates that the component A and the component B are “in contact”. For example, an adhesive layer may not be between the input sensing layer ISU and the display panel DP. As used herein, the input sensing layer ISU may be referred to as a sensor layer.

The anti-reflector RPP may be on the input sensing layer ISU. The anti-reflector RPP may reduce reflectance of external light. The anti-reflector RPP may be directly provided on the input sensing layer ISU through a roll-to-roll process. The anti-reflector RPP may include a polarizing plate and/or a color filter layer. When anti-reflector RPP includes a color filter layer, the color filter layer may include a plurality of color filters in a set or predetermined arrangement. The color filters may be arranged in consideration of light emitting colors of pixels included in the display panel DP. For example, the color filter may include a first color filter, a second color filter, and a third color filter, which correspond to a first color pixel, a second color pixel, and a third color pixel. In addition, the anti-reflector RPP may further include a black matrix adjacent to the color filters. In an embodiment, the anti-reflector RPP may be omitted.

The window WM is on the anti-reflector RPP. The window WM and the anti-reflector RPP may be bonded through an adhesive layer AD. The adhesive layer AD may be a pressure sensitive adhesive film (PSA) and/or an optically clear adhesive (OCA).

In an embodiment of the present disclosure, the adhesive layer AD may be omitted, and the window WM may be directly on the anti-reflector RPP. An organic material, an inorganic material, and/or a ceramic material may be applied onto the anti-reflector RPP.

FIG. 4 is a plan view of a display panel DP according to an embodiment of the present disclosure. FIG. 4 shows some components of the display panel DP when viewed on a plane. In FIG. 4, some components of the display panel DP are shown in block form for convenience of illustration.

Referring to FIG. 4, the display panel DP may include a base layer BL, a plurality of pixels PX, a plurality of signal lines electrically connected to the pixels PX, a scan driving circuit SDV, a driving chip DIC, a light emitting driving circuit EDV, and a plurality of display pads DPD.

The base layer BL may include a first base region AA1, a second base region AA2, and a bending region BA that are divided in the second direction DR2. The second base region AA2 and the bending region BA may be a portion of the non-display region NDA. The bending region BA is between the first base region AA1 and the second base region AA2.

The first base region AA1 may be a region including the front surface IS of the display module DM shown in FIG. 2. The second base region AA2 is spaced apart from the first base region AA1 with the bending region BA therebetween. The second base region AA2 and the bending region BA may have smaller widths than the first base region AA1 in the first direction DR1. For example, the bending region BA and the second region AA2 may have smaller lengths than the first base region AA1 in the first direction DR1. As such, a region having a smaller length in the direction of a bending axis may be bent more easily. However, this is shown as an example, and the second base region AA2 and the bending region BA may have the same width as the first base region AA1 in the first direction DR1, and are not limited to any one embodiment.

The bending region BA may be bent with respect to the bending axis extending along the first direction DR1. However, the embodiment of the present disclosure is not limited thereto, and the bending region BA may not be bent. When the bending region BA is not bent, the second base region AA2 may face the same direction as the first base region AA1, and when the bending region BA is bent, the second base region AA2 may face a direction opposite to the first base region AA1.

The circuit board MB described above (FIG. 2) is physically connected to the second base region AA2. As the bending region BA is bent, the circuit board MB is positioned on a rear surface of the display panel DP. Accordingly, a region defining the front surface IS (FIG. 2) of the display module DM (FIG. 2) becomes the first base region AA1, and the second base region AA2 and the bending region BA are not viewed through the front surface IS. Thus, the display device DD (FIG. 1) may have a reduced bezel region BZA.

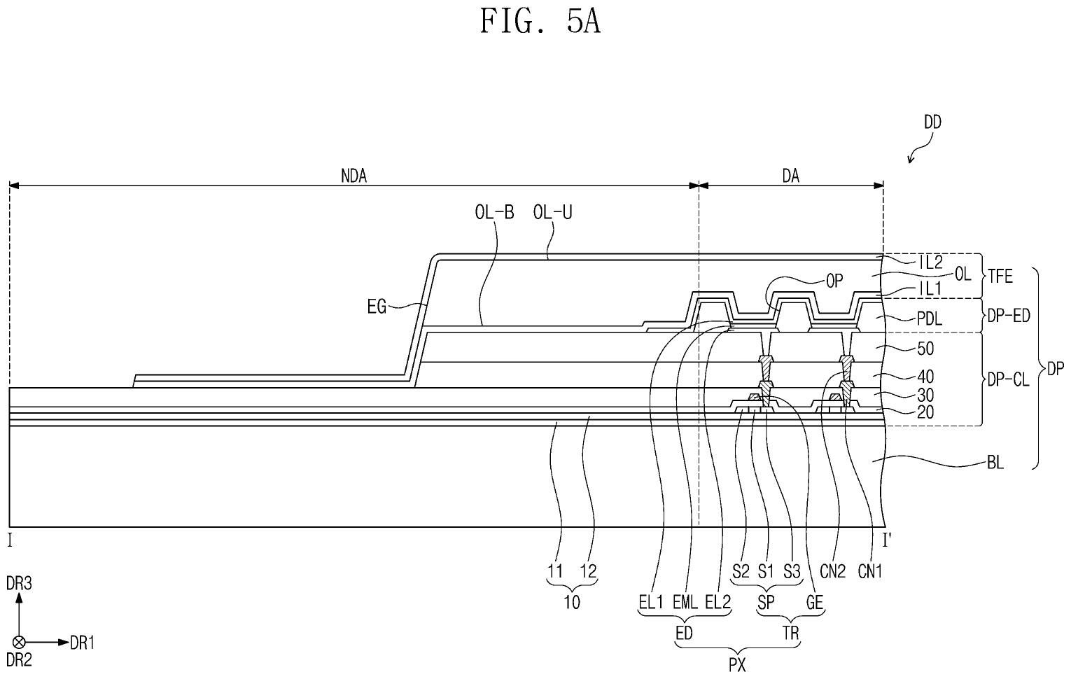

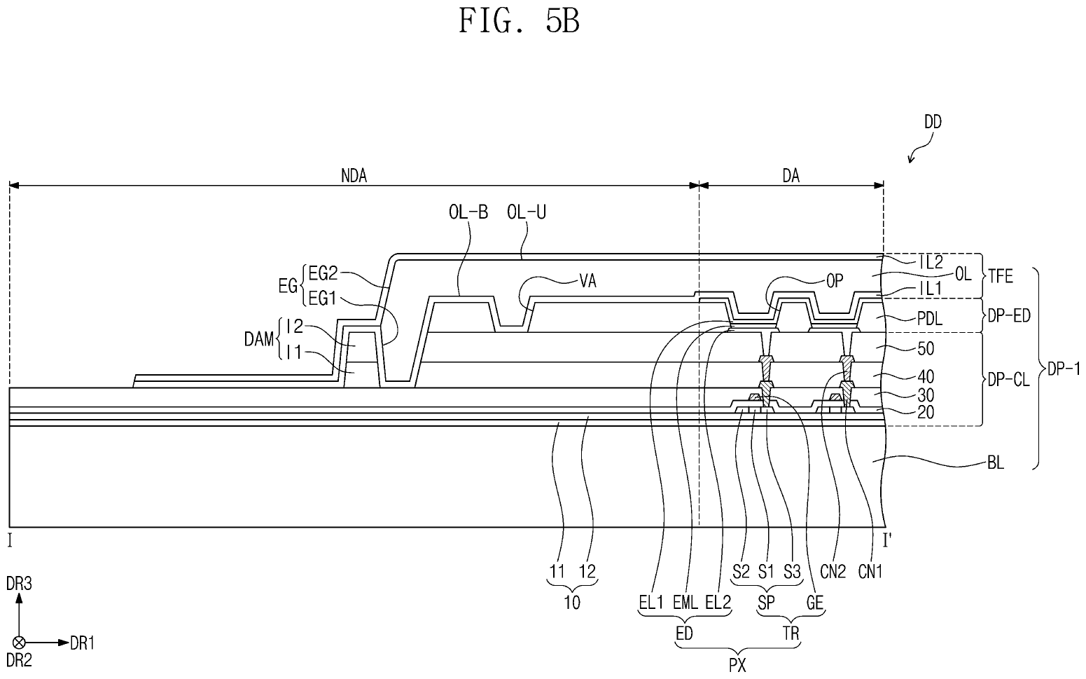

The base layer BL may include a non-display region NDA having a relatively very small width W_{DS}, compared to the display region DA. The non-display region NDA may have a first width W_{DS1} in the first direction DR1 and may have a second width W_{DS2} in the second direction DR2. For example, the first width W_{DS1} and the second width W_{DS2} in the non-display region NDA may each independently be about 1.5 μm or less, or about 1 μm or less. In the display panel DP of an embodiment, when the width W_{DS} (e.g., a sum of W_{DS1} and W_{DS2}) of the non-display region NDA is about 1.5 μm or less, dead space is reduced and an area of the display region DA is wider, and accordingly, improved display quality may be provided. The display device DD of an embodiment may not include or may minimally include (or may include a reduced amount of) an organic layer reflow prevention member due to the organic layer components of the encapsulation layer TFE, which will be further described herein below, and may thus reduce the width W_{DS} of the non-display region NDA, that is, the dead space. The pixels PX each include a light emitting element ED and a transistor TR (e.g., a thin film transistor) (see FIG. 5A) connected to the light emitting element ED. The shape of the display panel DP shown in FIG. 4 may be substantially the same as the shape of the base layer BL when viewed on a plane. In the present embodiment, the display region DA and the non-display region NDA may be divided according to the presence or absence of a light emitting element ED.

In FIG. 4, the pixels PX are shown to be in the display region DA. The display region DA may be a region in which an image IM is displayed (FIG. 1). This is shown as an example, and some components of each of the pixels PX may include a thin film transistor in the non-display region NDA, and are not limited to any one embodiment.

The scan driving circuit SDV, the driving chip DIC, and the light emitting driving circuit EDV may be in the non-display region NDA. The driving chip DIC may include a data driving circuit. In an embodiment, the scan driving circuit SDV and the light emitting driving circuit EDV may each be in the non-display region NDA adjacent to the long sides of the base layer BL. The driving chip DIC may be in the non-display region NDA adjacent to the short sides of the base layer BL. However, the embodiment of the present disclosure is not limited thereto, and in an embodiment, at least one selected from the scan driving circuit SDV, the light emitting driving circuit EDV, and the driving chip DIC may overlap the display region DA. Accordingly, an area of the non-display region NDA may be reduced, and the display device DD (FIG. 1) having a reduced bezel region BZA may be obtained. As used herein, the non-display region NDA and the bezel region BZA may be referred to as a dead space.

The plurality of signal lines may include scan lines SGL1 to SGLm, data lines DL1 to DLn, light emitting lines LEL1 to LELm, first and second control lines CSL1 and CSL2, a power line PL, and connection lines CNL. A plurality of display pads DPD may be connected to each of the data lines DL1 to DLn, the first and second control lines CSL1 and CSL2, and the power line PL. In this case, m and n represent a natural number.

The pixels PX are each connected to a corresponding scan line among the scan lines SGL1 to SGLm, and a corresponding data line among the data lines DL1 to DLn, and a corresponding light emitting line among the light emitting lines LEL1 to LELm. In some embodiments, more types (or kinds) of signal lines may be provided in the display panel DP according to components of a pixel driving circuit of the pixels PX.

The scan lines SGL1 to SGLm may extend in the first direction DR1 and be connected to the scan driving circuit SDV. The data lines DL1 to DLn may extend in the second direction DR2, and be connected to the driving chip DIC via the bending region BA. The light emitting lines LEL1 to LELm may extend in the first direction DR1 and be connected to the light emitting driving circuit EDV.

The power line PL may include a portion extending in the second direction DR2 and a portion extending in the first direction DR1. Of the power line PL, a portion extending in the first direction DR1 and a portion extending in the second direction DR2 may be on different layers. The portion of the power line PL, which extends in the second direction DR2, may extend to the second base region AA2 via the bending region BA. The power line PL may provide a first voltage to the pixels PX.

The connection lines CNL may extend in the first direction DR1 and be arranged in the second direction DR2 to be connected to the power line PL and the pixels PX. The connection lines CNL may be electrically connected to the power line PL by being on a different layer. However, the embodiment of the present disclosure is not limited thereto, and the connection lines CNL and the power line PL may be formed as a singly body on the same layer. A first voltage may be applied to the pixels PX through the power line PL and the connection lines CNL connected to each other.

A first control line CSL1 may be connected to the scan driving circuit SDV, and may extend toward a lower end of the second base region AA2 via the bending region SUB. The second control line CSL2 may be connected to the light emitting driving circuit EDV, and may extend toward a lower end of the second base region AA2 via the bending region SUB.

When viewed on a plane, the display pads DPD may be adjacent to the lower end of the second base region AA2. The driving chip DIC, the power line PL, the first control line CSL1, and the second control line CSL2 may be connected to the display pads DPD. The circuit board MB may be electrically connected to the display pads DPD through an anisotropic conductive adhesive layer.

The scan driving circuit SDV may generate scan signals in response to the scan control signal. The scan signals may be applied to the pixels PX through the scan lines SGL1 to SGLm. The driving chip DIC may generate data voltages corresponding to the image signals in response to the data control signal. The data voltages may be applied to the pixels PX through the data lines DL1 to DLn. The light emitting driving circuit EDV may generate light emitting signals in response to the light emitting control signal. The light emitting signals may be applied to the pixels PX through the light emitting lines LEL1 to LELm.

The pixels PX may be provided with the data voltages in response to the scan signals. The pixels PX may display an image by emitting light of luminance corresponding to the data voltages in response to the light emitting signals. The light emitting duration of the pixels PX may be controlled by the light emitting signals. Accordingly, the display panel DP may output images through the display region DA by the pixels PX.

FIG. 5A is a cross-sectional view of some components of the display device DD according to an embodiment of the present disclosure. FIG. 5A shows a cross-section of the display panel DP corresponding to the display region DA and the non-display region NDA adjacent to the display region DA as an example. FIG. 5A is a cross-sectional view of the display panel DP corresponding to I-I′ of FIG. 4.

Referring to FIG. 5A, the display panel DP may include a base layer BL, a circuit layer DP-CL, a display element layer DP-ED, and an encapsulation layer TFE. The same descriptions above may apply to each component of the display panel DP.

The base layer BL may include a glass substrate, a metal substrate, a polymer substrate, and/or an organic/inorganic composite material substrate. In an embodiment, the base layer BL may include a synthetic resin layer. For example, the synthetic resin layer may include at least one selected from an acryl-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin.

However, the material of the base layer BL is not limited to the examples described above.

The circuit layer DP-CL may be on the base layer BL and may include a plurality of insulating layers 10, 20, 30, 40, and 50. The circuit layer DP-CL may include an insulating layer, a semiconductor pattern, a conductive pattern, a signal line, and/or the like. In a method for manufacturing a display panel DP, the insulating layer, the semiconductor layer, and the conductive layer may be formed on the base layer BS through methods such as coating and/or vapor deposition, and then selectively patterned through a photolithography process a plurality of times. Thereafter, the semiconductor pattern, the conductive pattern, and the signal line included in the circuit layer DP-CL may be formed.

FIG. 5A shows the first to fifth insulating layers 10 to 50 included in the circuit layer DP-CL, and semiconductor patterns and conductive patterns between the base layer BL and the first to fifth insulating layers 10 to 50. However, the cross section of the circuit layer DP-CL shown in FIG. 5A is presented as an example, and a stack structure of the circuit layer DP-CL may be variously suitably modified according to a process step, a process method, and/or components of a light emitting element ED included in the pixel PX.

The first insulating layer 10 may be on the base layer BL. The first insulating layer 10 may include a barrier layer 11 and a buffer layer 12. The barrier layer 11 prevents or reduces introduction of foreign substances from the outside. The barrier layer 11 may include at least one selected from a silicon oxide layer and a silicon nitride layer. Each of these may be provided in plurality, and silicon oxide layers and silicon nitride layers may be alternately stacked.

The buffer layer 12 may be on the barrier layer 11. The buffer layer 12 may increase a bonding force between the base layer BL and the semiconductor patterns and/or the conductive patterns. The buffer layer 12 may include at least one selected from a silicon oxide layer and a silicon nitride layer. The silicon oxide layer and the silicon nitride layer may be alternately stacked.

The pixels PX may be on the first insulating layer 10. The pixels PX may each have an equivalent circuit including a transistor TR, at least one capacitor, and a light emitting element ED, and the equivalent circuit diagram of the pixels PX may be modified in various suitable forms. The semiconductor patterns may be arranged by set or specific rules over the pixels PX. FIG. 5A shows some components of one pixel PX as an example.

The transistor TR may include a semiconductor pattern SP and a gate GE. The semiconductor pattern SP may be on the first insulating layer 10. The semiconductor pattern SP may include a silicon semiconductor, and may include a single-crystal silicon semiconductor, a poly-silicon semiconductor, or an amorphous silicon semiconductor. The semiconductor pattern SP may include an oxide semiconductor. The semiconductor pattern SP according to an embodiment of the present disclosure may be formed of various suitable materials as long as the materials have semiconductor properties, and is not limited to any one embodiment.

A channel S1, a source S2, and a drain S3 of the transistor TR may be formed from the semiconductor pattern SP. The semiconductor pattern SP may be divided into a plurality of regions according to conductivity (e.g., electrical conductivity). For example, the semiconductor pattern SP may have different electrical properties according to with/without doping or with/without metal oxide reduction. A highly conductive region (e.g., a highly electrically conductive region) of the semiconductor pattern SP may serve as an electrode or a signal line, and may correspond to the source S2 and the drain S3 of the transistor TR. The non-doped or non-reduced region having relatively low conductivity may correspond to the channel S1 (or active) of the transistor TR.

In an embodiment, the semiconductor pattern SP may include a first region having high conductivity (e.g., high electrical conductivity) and a second region having low conductivity (e.g., low electrical conductivity). The first region may be doped with an N-type dopant or a P-type dopant. A P-type transistor may include a doped region which is doped with the P-type dopant, and an N-type transistor may include a doped region doped with the N-type dopant. The second region may be a non-doped region or may be doped in a lower concentration than the first region.

In an embodiment, the semiconductor pattern SP may include a plurality of regions divided according to with/without metal oxide reduction. A region in which metal oxides are reduced (hereinafter, reduction region) has greater conductivity (e.g., greater electrical conductivity) than a region in which metal oxides are not reduced (hereinafter, non-reduction region). The reduction region may substantially serve as an electrode of the transistor TR, and the non-reduction region may substantially correspond to the channel of the transistor TR.

The second to fifth insulating layers 20 to 50 may be stacked on the semiconductor pattern SP. The second to fifth insulating layers 20 to 50 may be inorganic layers and/or organic layers. For example, the inorganic layer may include at least one selected from aluminum oxide, titanium oxide, silicon oxide, silicon nitride, silicon oxynitride, zirconium oxide, and hafnium oxide. The organic layer may include a phenol-based polymer, an acryl-based polymer, an imide-based polymer, an arylether-based polymer, an amide-based polymer, a fluorine-based polymer, a p-xylene-based polymer, a vinyl alcohol-based polymer, or a combination thereof. However, the material of the insulating layer is not limited to the examples above.

The second insulating layer 20 may be on the first insulating layer 10 and may cover the semiconductor pattern SP. The second insulating layer 20 may be between the semiconductor pattern SP and the gate GE of the transistor TR. In an embodiment, the second insulating layer 20 may be an inorganic layer having a single-layered or multi-layered structure. The second insulating layer 20 may be a single-layered silicon oxide layer.

The gate GE may be on the second insulating layer 20. The gate GE may be a portion of the conductive pattern of the circuit layer DP-CL. When viewed on a plane, the gate GE may overlap the channel S1 of the transistor TR. In the doping process of the semiconductor pattern SP, the gate GE may serve as a mask.

The transistor TR of FIG. 5A is shown as an example, and the source S2 or the drain S3 may be electrodes formed independently from the semiconductor pattern SP. In this case, the source S2 and the drain S3 may contact the semiconductor pattern SP or be connected to the semiconductor pattern SP through an insulating layer. In addition, in an embodiment, the gate GE may be below the semiconductor pattern SP. The transistor TR according to an embodiment of the present disclosure may be formed in various suitable forms and is not limited to any one embodiment.

The third insulating layer 30 may be on the second insulating layer 20 and may cover the gate GE. In an embodiment, the third insulating layer 30 may be an inorganic layer having a single-layered or multi-layered structure. In the present embodiment, the third insulating layer 30 may be a single-layered silicon oxide layer.

The fourth insulating layer 40 may be on the third insulating layer 30. In an embodiment, the fourth insulating layer 40 may be an organic layer having a single-layered or multi-layered structure. For example, the fourth insulating layer 40 may be a single-layered polyimide-based resin. However, the embodiment of the present disclosure is not limited thereto, and the fourth insulating layer 40 may include at least any one selected from among an acrylic-based resin, a methacrylate-based resin, polyisoprene, a vinyl-based resin, an epoxy-based resin, a urethane-based resin, a cellulose-based resin, a siloxane-based resin, a polyamide-based resin, and a perylene-based resin. The organic layer which will be further described herein below may include at least one of the materials described above.

A first connection electrode CN1 may be on the third insulating layer 30. A second connection electrode CN2 may be on the fourth insulating layer 40. The first connection electrode CN1 may be electrically connected to the semiconductor pattern SP through a contact hole passing through the second insulating layer 20 and the third insulating layer 30. The second connection electrode CN2 may be electrically connected to the first connection electrode CN1 through a contact hole passing through the fourth insulating layer 40.

In an embodiment, at least one of the first connection electrode CN1 or the second connection electrode CN2 may be omitted. In some embodiments, an additional connection electrode connecting the light emitting element ED and the transistor TR may be further provided. Depending on the number of insulating layers between the light emitting element ED and the transistor TR, a method of the electrical connection between the light emitting element ED and the transistor TR may be variously suitably changed, and is limited to any one embodiment.

The fifth insulating layer 50 may be on the fourth insulating layer 40 and may cover the second connection electrode CN2. The fifth insulating layer 50 may be an organic layer and/or an inorganic layer, and have a single-layered or multi-layered structure. At least a portion of the upper surface of each of the plurality of insulating layers 10, 20, 30, 40, and 50 may have a flat surface parallel (or substantially parallel) to the upper surface of the base layer BL.

The display element layer DP-ED may be on the circuit layer DP-CL. The display element layer DP-ED may include the light emitting element ED and the pixel defining film PDL. The light emitting element ED may be electrically connected to the transistor TR to form the pixel PX. The light emitting element ED may be on the display region DA to emit light. For example, the light emitting element ED may include an organic light emitting element, a quantum dot light emitting element, a micro LED light emitting element, and/or a nano LED light emitting element. However, the embodiment of the present disclosure is not limited thereto, and the light emitting element ED may include various suitable embodiments as long as light is generated and/or an amount of light is controlled according to electrical signals.

The light emitting element ED may be on the fifth insulating layer 50. The light emitting element ED may include a first electrode EL1, an emission layer EML, and a second electrode EL2. A first electrode EL1 may be on the fifth insulating layer 50. The first electrode EL1 may be connected to the second connection electrode CN2 through a contact hole passing through the fifth insulating layer 50.

The first electrode EL1 may be an anode or a cathode. However, the embodiment of the present disclosure is not limited thereto. In addition, the first electrode EL1 may be a pixel electrode. The first electrode EL1 may be a transmissive electrode, a transflective electrode, or a reflective electrode. The first electrode may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stack structure of LiF and Ca), LiF/AI (a stack structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may have a three-layer structure of ITO/Ag/ITO, but is not limited thereto. In addition, the first electrode EL1 may include the above-described metal materials, a combination of two or more metal materials selected from the above-described metal materials, and/or oxides of the above-described metal materials, and the embodiment of the present disclosure is not limited thereto.

The pixel defining film PDL may be on the first electrode EL1 and the fifth insulating layer 50 and may expose at least a portion of the first electrode EL1. For example, a pixel opening OP exposing at least a portion of the first electrode EL1 may be defined in the pixel defining film PDL.

The pixel defining film PDL may be formed of a polymer resin. For example, the pixel defining film PDL may include a polyacrylate-based resin and/or a polyimide-based resin. The pixel defining films PDL may be formed by further including an inorganic material in addition to the polymer resin. In addition, the pixel defining film PDL may be formed of an inorganic material. For example, the pixel defining film PDL may be formed from silicon nitride (SiNₓ), silicon oxide (SiOₓ), silicon oxynitride (SiOₓN_{y}), and/or the like.

In an embodiment, the pixel defining film PDL may further include a light absorbing material. The pixel defining film PDL may include a black coloring agent. The black coloring agent may include a black dye and/or a black pigment. The black coloring agent may include carbon black, a metal such as chromium, and/or an oxide thereof.

The emission layer EML may be on the first electrode EL1. Emission layer EML may correspond to the pixel opening OP of the pixel defining film PDL. For example, the emission layer EML may be in the pixel opening OP defined in the pixel defining film PDL to be distinguished from the adjacent emission layer EML of the light emitting element ED. However, the embodiment of the present disclosure is not limited thereto, and the emission layer EML may extend toward an upper surface of the pixel defining film PDL and be commonly provided in a plurality of pixels PX.

The emission layer EML may provide light of a set or predetermined color. The emission layer EML may include an organic light emitting material and/or an inorganic light emitting material. For example, the emission layer EML may include a fluorescent material and/or a phosphorescent material, a metal organic complex light emitting material, and/or quantum dots. FIG. 5A shows a patterned single-layer emission layer EML as an example, but the embodiment of the present disclosure is not limited thereto. For example, the emission layer EML may extend toward the upper surface of the pixel defining film PDL and be commonly provided to the plurality of pixels PX. In addition, the emission layer EML may have a multi-layered structure. For example, the emission layer EML may include a main emission layer and an auxiliary emission layer on the main emission layer. The main emission layer and the auxiliary emission layer may be provided to have different thicknesses according to the wavelength of emitted light, and the disposition of the auxiliary emission layer may allow the resonance distance of the light emitting element ED to be regulated. In addition, the disposition of the auxiliary emission layer may improve color purity of light emitted from the emission layer EML.

The second electrode EL2 may be on the emission layer EML. The second electrode EL2 may be commonly provided in the pixels PX. The second electrode EL2 may be provided with a common voltage, and may be referred to as a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include at least one selected from Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or an oxide thereof.

In some embodiments, the light emitting element ED may further include light emitting functional layers between the first electrode EL1 and the second electrode EL2. For example, the light emitting element ED may include a hole control layer (or hole control region) between the first electrode EL1 and the emission layer EML, and/or may include an electron control layer (or electron control region) between the emission layer EML and the second electrode EL2. The hole control layer (or hole control region) may include a hole transport layer and/or a hole injection layer, and the electron control layer (or electron control region) may include an electron transport layer and/or an electron injection layer.

In addition, the light emitting element ED may further include a capping layer on the second electrode EL2. The capping layer may be an organic layer and/or an inorganic layer. For example, when the capping layer includes an inorganic material, the inorganic material may include an alkali metal compound such as LiF, an alkaline earth metal compound such as MgF₂, SION, SiNₓ, and/or SiO_{y}. For example, when the capping layer includes an organic material, the organic material may include α-NPD, NPB, TPD, m-MTDATA, Alq₃ CuPc, N4, N4, N4′, N4′-tetra (biphenyl-4-yl) biphenyl-4,4′-diamine (TPD15), 4,4′,4″-Tris (carbazol-9-yl) triphenylamine (TCTA), and/or the like, and/or may include epoxy resins and/or acrylates such as methacrylates.

A first voltage may be applied to the first electrode EL1 through the transistor TR, and a common voltage may be applied to the second electrode EL2. Holes and electrons injected into the emission layer EML are bonded to form excitons, and the excitons transition to a ground state, and accordingly, the light emitting element ED may emit light through the display region DA.

In an embodiment, the encapsulation layer TFE may cover the display element layer DP-ED. The encapsulation layer TFE may be on the display element layer DP-ED and may cover the pixel defining film PDL and the light emitting element ED. For example, the encapsulation layer TFE may encapsulate the light emitting element ED. The encapsulation layer TFE may be a thin film encapsulation layer.

The encapsulation layer TFE may include at least one insulating layer, and the insulating layer may be provided as first to second inorganic layers IL1 and IL2 or an organic layer OL. In an embodiment, the encapsulation layer TFE may include a plurality of insulating layers, and at least one of the plurality of insulating layers is provided as the organic layer OL and at least one is provided as the first to second inorganic layers IL1 and IL2. The encapsulation layer TFE of an embodiment may include at least one first to second inorganic layer IL1 and/or IL2 and at least one organic layer OL. The encapsulation layer TFE may include a plurality of first to second inorganic layers IL1 and IL2 and at least one organic layer OL between each of the plurality of first to second inorganic layers IL1 and IL2. In an embodiment, the encapsulation layer TFE may include a first inorganic layer IL1, an organic layer OL, and a second inorganic layer IL2.

The first inorganic layer IL1 may be on the second electrode EL2. The first inorganic layer IL1 may extend from the display region DA and be on the non-display region NDA. The organic layer OL may be on the first inorganic layer IL1. The second inorganic layer IL2 may be on the organic layer OL and may cover the organic layer OL. However, the stack structure of the encapsulation layer TFE is not limited to the described embodiment.

The first inorganic layer IL1, the second inorganic layer IL2, and the organic layer OL may each be formed to correspond to the shapes of components below the first inorganic layer IL1, the second inorganic layer IL2, and the organic layer OL. For example, an upper surface of the first inorganic layer IL1 may have a step according to a structure of the components of the display panel DP below the first inorganic layer IL1. The first inorganic layer IL1 may be provided along a step of the pixel opening OP defined in the pixel defining film PDL.

The organic layer OL may include a lower surface OL-B contacting the first inorganic layer IL1, an upper surface OL-U facing the lower surface OL-B and contacting the second inorganic layer IL2, and an edge EG connecting the lower surface OL-B and the upper surface OL-U. The upper surface OL-U of the organic layer OL may provide a flat surface to components on the encapsulation layer TFE. The lower surface OL-B of the organic layer OL may have a step along the pixel opening OP defined in the pixel defining film PDL on the first inorganic layer IL1. The edge EG of the organic layer OL may substantially define the shape of the organic layer OL formed on the base layer BL. The edge EG of the organic layer OL may correspond to an end point of a position of forming the organic layer OL.

The first inorganic layer IL1 and the second inorganic layer IL2 may protect the light emitting element ED from moisture and/or oxygen. For example, the first inorganic layer IL1 and the second inorganic layer IL2 may include at least one selected from aluminum oxide, titanium oxide, silicon oxide, silicon nitride, silicon oxynitride, zirconium oxide, and hafnium oxide, but the materials included in the first inorganic layer IL1 and the second inorganic layer IL2 are not limited to the examples above.

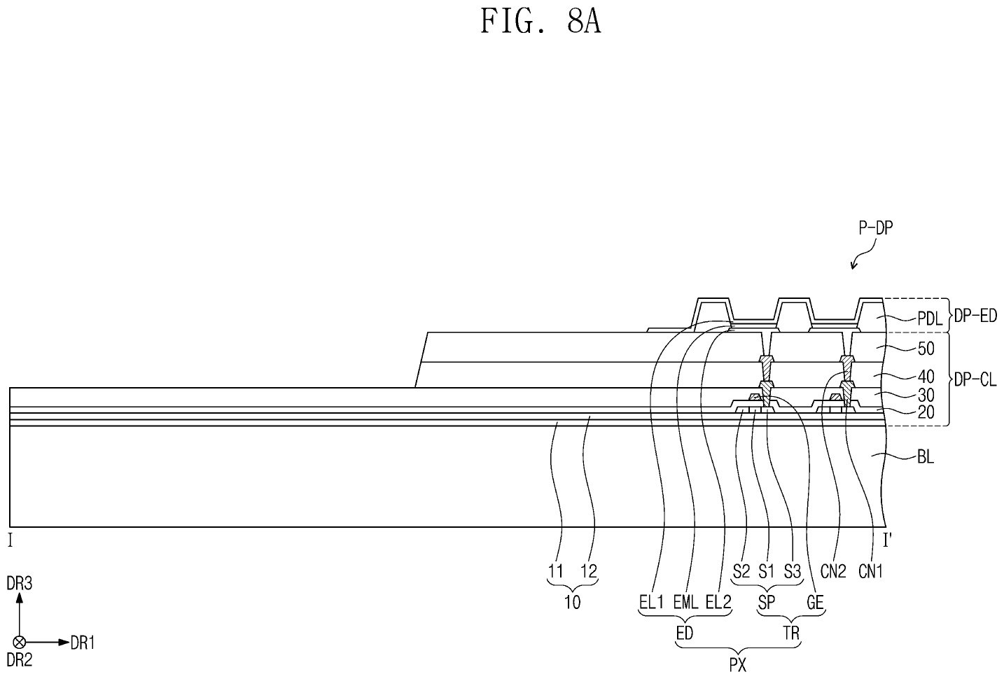

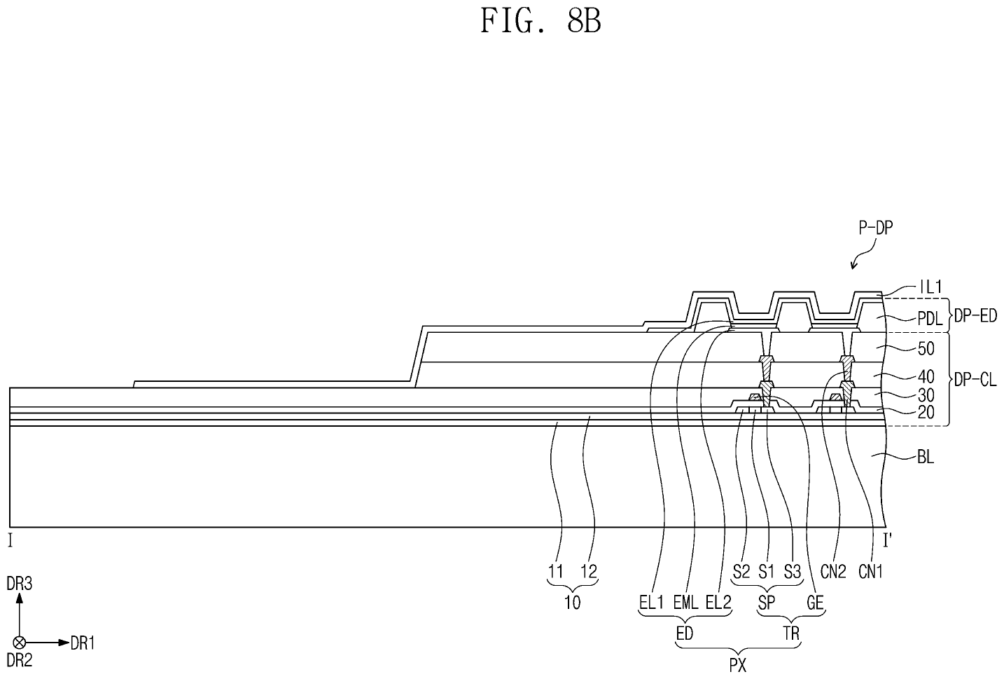

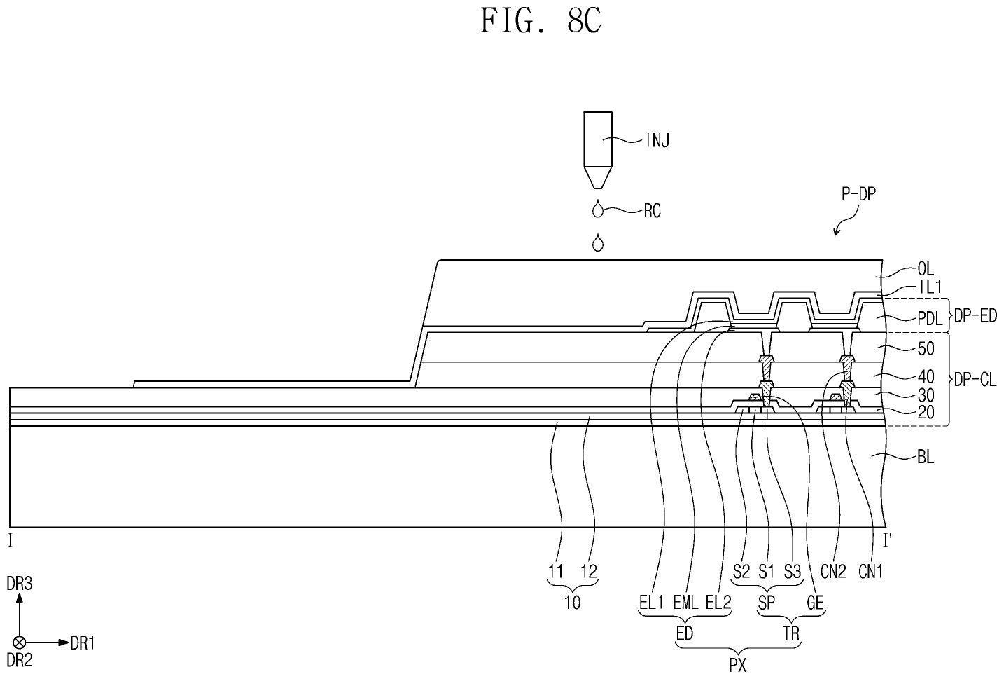

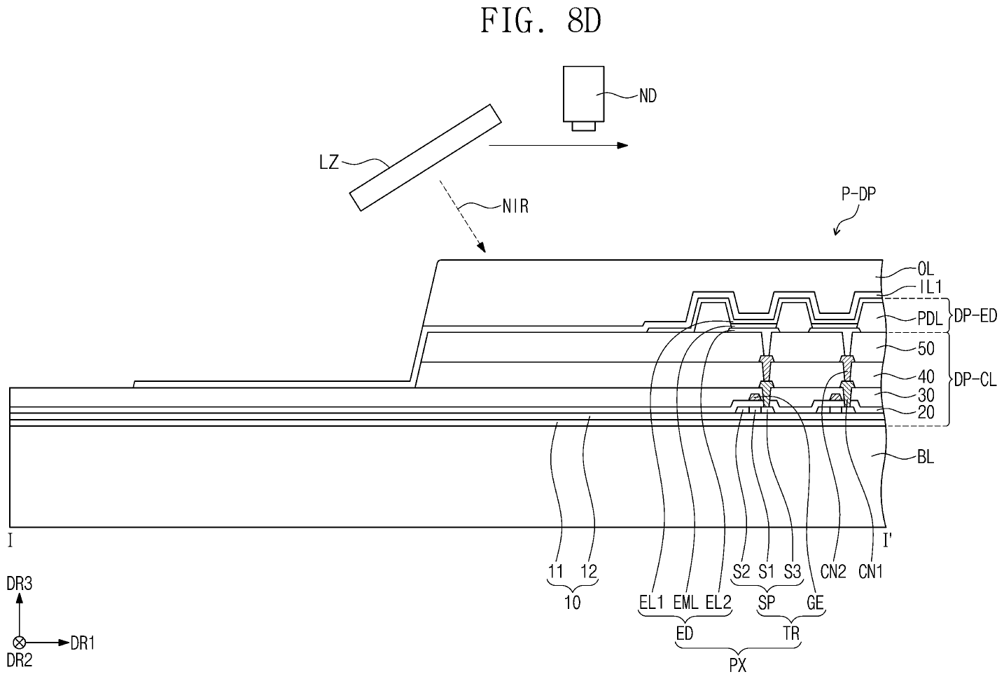

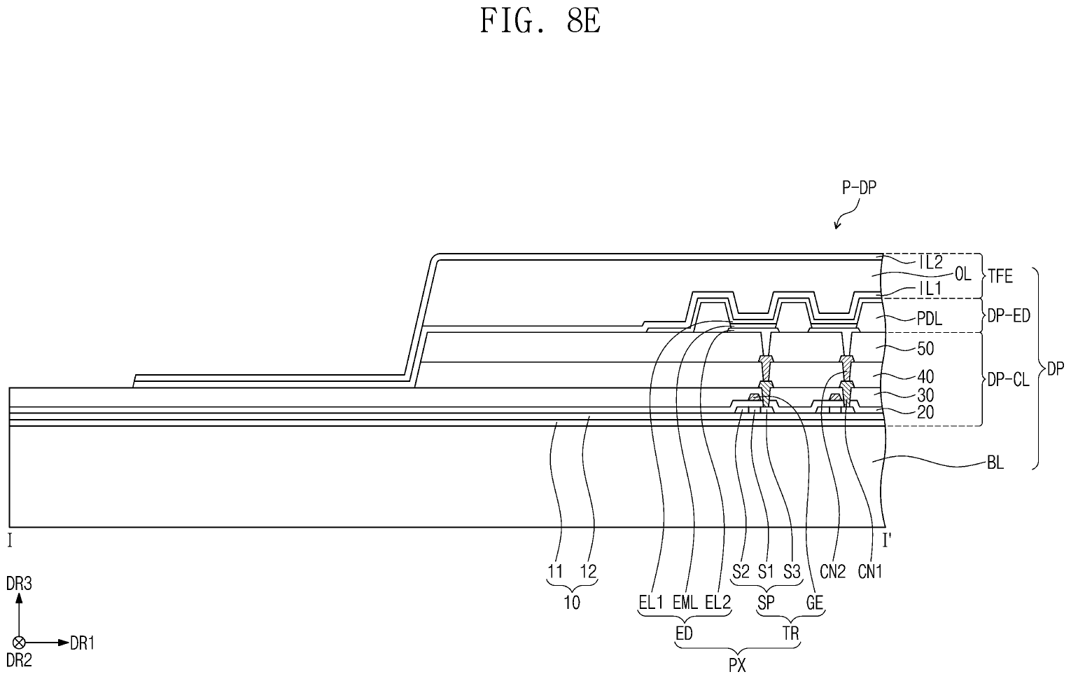

The organic layer OL may protect the light emitting element ED from foreign substances such as dust particles. The organic layer OL may include a base resin and a near-infrared absorbing dye. For example, the organic layer OL may be formed from a resin composition RC (see FIG. 8C) including a base resin and a near-infrared absorbing dye.

The base resin may include at least one selected from an acryl-based resin, an epoxy-based resin, and a silicone-based resin. However, the material of the base resin is not limited to the examples above. As used herein, a compound indicated by “˜˜ based” may indicate a compound including “˜˜”. For example, an acryl-based resin corresponds to a resin material including an acrylate group.

In an embodiment, the near-infrared absorbing dye is a material that may be stably dissolved or dispersed in the base resin, and may be a dye that does not (or substantially does not) absorb visible light. The near-infrared absorbing dye of an embodiment may be a dye that absorbs near-infrared light of a wavelength of 750 nm or greater. For example, the near-infrared absorbing dye may be a dye that absorbs light in a wavelength range of about 750 nm to about 2500 nm. The near-infrared absorbing dye may include a sulfonic group in molecules, an indoline moiety, and/or the like.

For example, the near-infrared absorbing dye may include at least one selected from the compounds of Compound Group 1 below. However, the embodiment of the present disclosure is not limited thereto. The near-infrared absorbing dye may be used without particular limitation as long as it does not (or substantially does not) impair visible light transmittance of the organic layer OL.

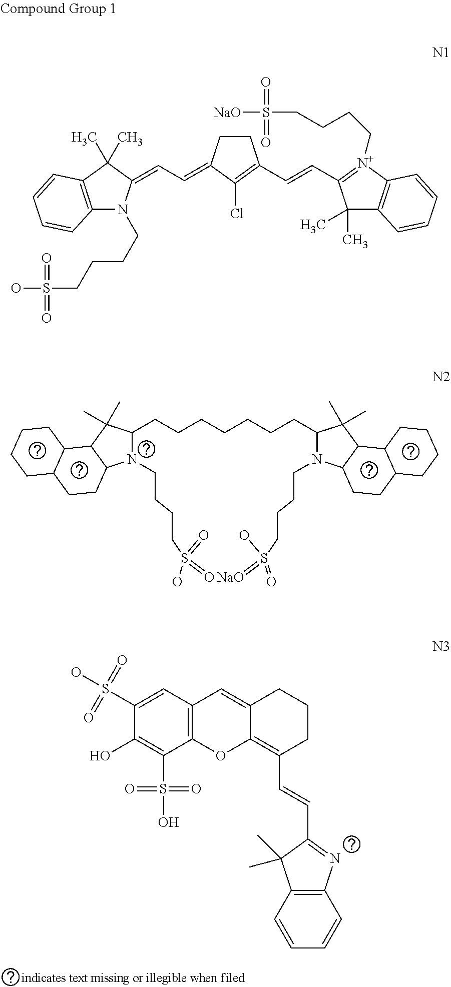

In the display panel DP of an embodiment, a position in which the organic layer OL is formed may be determined by including the near-infrared absorbing dye in the organic layer OL. For example, the display panel DP may identify the position of forming the edge EG of the organic layer OL to determine an end point in which the organic layer OL is formed. Accordingly, in the display panel DP of an embodiment, when the organic layer OL is formed on a portion other than the desired position, the portion may be easily identified. Accordingly, the display device DD of an embodiment does not include or minimally includes (or includes a reduced amount of) a separate organic layer reflow prevention member such as a dam to simplify components of the display panel DP on the non-display region NDA, and thus width WDs (FIG. 4) and an area of the non-display region NDA may be reduced. For example, the display device DD of an embodiment reduces a dead space of the display panel DP by the components of the organic layer OL described above, and may thus provide excellent display quality.

The organic layer OL may exhibit excellent transmittance even when the near-infrared absorbing dye described above is included. For example, the organic layer OL may have a visible light transmittance of about 97% or greater. In some embodiments, the visible light transmittance of the organic layer OL including the near-infrared absorbing dye may be about 99% or greater.

In an embodiment, the organic layer OL may have a thickness of about 0.3 μm to about 20 μm in the encapsulation layer TFE. The encapsulation layer TFE may have an optimized or improved thickness and transmittance by setting the thickness of the organic layer OL to about 0.3 μm to about 20 μm.

FIG. 5B is a cross-sectional view of some components of the display device DD according to an embodiment of the present disclosure. FIG. 5B shows a cross-section of a display panel DP-1 corresponding to the display region DA and the non-display region NDA adjacent to the display region DA as an example. FIG. 5B includes the same components as the display panel DP of FIG. 5A, but some components are different. Hereafter, overlapping descriptions of the components will not be given again and differences will be mainly described.

In an embodiment, the display panel DP-1 may further include an organic layer reflow prevention member in the non-display region NDA. For example, in the display panel DP-1, the organic layer reflow prevention member may further include at least one recess portion VA and/or at least one dam portion DAM.

The display panel DP-1 may include at least one recess portion VA defined in the pixel defining film PDL. The recess portion VA may be spaced apart from the pixel opening OP and in the non-display region NDA. The recess portion VA may be recessed from an upper surface to a lower surface of the pixel defining film PDL along the third direction DR3 of the pixel defining film PDL. In an embodiment, the recess portion VA may control reflow of the organic layer OL. Although the display panel DP-1 including one recess portion VA is shown in FIG. 5B as an example, the embodiment of the present disclosure is not limited thereto. For example, the display panel DP-1 may include a plurality of recess portions VA defined in the pixel defining film PDL.

The recess portion VA may be covered by the first inorganic layer IL1. The first inorganic layer IL1 in the recess portion VA may have a step due to the shape of the recess portion VA. The first inorganic layer IL1 may have a step along the recess portion VA. The organic layer OL may be on the first inorganic layer IL1 and may fill the recess portion VA. For example, a lower surface OL-B of the organic layer OL may be in contact with an upper surface of the first inorganic layer IL1 having a step, and an upper surface OL-U of the organic layer OL may have a flat surface parallel (or substantially parallel) to the upper surface of the base layer BL. The second inorganic layer IL2 may contact the upper surface OL-U of the organic layer OL. The second inorganic layer IL2 may be spaced apart from the first inorganic layer IL1 with the organic layer OL therebetween in the display region PA.

The display panel DP-1 of an embodiment may further include a dam portion DAM in the non-display region NDA. The dam portion DAM may be adjacent to the edge EG of the organic layer OL. The dam portion DAM may be closer to the outside of the non-display region NDA than the recess portion VA. For example, the recess portion VA and the dam portion DAM may be sequentially arranged in a direction away from the display region DA. For example, the dam portion DAM may be spaced apart from the display region DA and the light emitting element ED, compared to the recess portion VA. The dam portion DAM may control the flow of the organic layer OL toward an outer edge of the base layer BL and prevent or reduce reflow of the organic layer OL. FIG. 5B shows one dam portion DAM as an example, but the embodiment of the present disclosure is not limited thereto, and a plurality of dam portions DAM may be provided.

The dam portion DAM may include a plurality of layers. For example, the dam portion DAM may include a first layer 11 and a second layer 12. At least some of the first to second layers 11 and 12 included in the dam portion DAM may be formed concurrently during the formation of the insulating layers 10 to 50 of the circuit layer DP-CL or the pixel defining film PDL. In an embodiment, the first layer 11 may include the same material as the fifth insulating layer 50 and may be formed through the same process. The second layer 12 may include the same material as the pixel defining film PDL and may be formed through the same process. However, the dam portion DAM may have a single-layered structure or may have a multi-layered structure, which is greater than what is shown, and the embodiment of the present disclosure is not limited to any one embodiment.

The dam portion DAM may be covered by the first inorganic layer IL1. The organic layer OL may extend to the dam portion DAM on the first inorganic layer IL1. At least a portion of the edge EG of the organic layer OL may contact the first inorganic layer IL1 on the dam portion DAM. For example, the edge EG of the organic layer OL may include a first edge EG1 contacting the first inorganic layer IL1 and a second edge EG2 non-contacting the first inorganic layer IL1.

In an embodiment, the organic layer OL may be on one side of the dam portion DAM on a cross section perpendicular (or substantially perpendicular) to the base layer. For example, the organic layer OL may be on one side of the dam portion DAM adjacent to the display region DA. In FIG. 5B, the organic layer OL is provided throughout one side of the dam portion DAM adjacent to the display area DA, but the embodiment of the present disclosure is not limited thereto. The organic layer OL may be on at least a portion of one side of the dam portion DAM adjacent to the display region DA with the first inorganic layer IL1 therebetween.

In an embodiment, the flow of the organic layer OL is controlled by the dam portion DAM, and accordingly, the organic layer OL may not be on an upper surface of the dam portion DAM and one side of the dam portion DAM adjacent to an edge of the base layer BL. Accordingly, the first inorganic layer IL1 on the dam portion DAM may contact the second inorganic layer IL2. For example, the second inorganic layer IL2 may be directly on the first inorganic layer IL1 on the upper surface of the dam portion DAM and on one side of the dam portion DAM adjacent to the edge of the base layer BL.

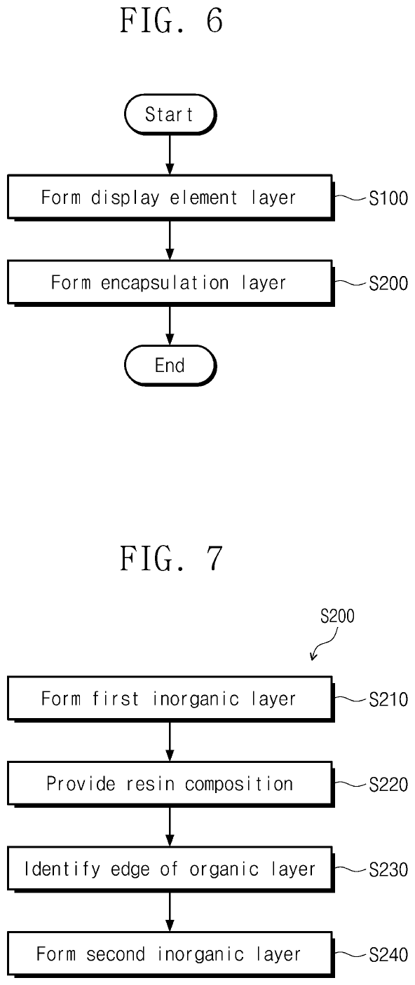

FIG. 6 is a flowchart showing each step in a method for manufacturing a display device according to an embodiment of the present disclosure. FIG. 7 is a flowchart showing some steps in a method for manufacturing a display device according to an embodiment of the present disclosure. FIG. 7 is a flowchart showing steps of forming an encapsulation layer in a method for manufacturing a display device according to an embodiment of the present disclosure. FIGS. 8A-8E are cross-sectional views sequentially showing some steps in a method for manufacturing a display device according to an embodiment of the present disclosure. Hereinafter, when describing the display device according to an embodiment of the present disclosure with reference to FIGS. 6-8E, the same reference symbols are given to components that are the same as the components described above, and redundant descriptions will not be repeated here.

Referring to FIGS. 3, 6, and 7, a method for manufacturing a display device according to an embodiment may include forming a display element layer (S100) and forming an encapsulation layer (S200). As described with reference to FIG. 3 and the like, the display device DD may include a display panel DP. The display panel DP is divided into a display region DA and a non-display region NDA, and may include a base layer BL, a circuit layer DP-CL, a display element layer DP-ED, and an encapsulation layer TFE, which are sequentially stacked. In the method for manufacturing a display device according to an embodiment, the forming of the encapsulation layer TFE included in the display panel DP (S200) may include forming a first inorganic layer (S210), providing a resin composition (S220), identifying an edge of an organic layer (S230), and forming a second inorganic layer (S240).

In an embodiment, in the forming of a display element layer (S100), the display element layer DP-ED may be formed on the base layer BL. The display element layer DP-ED is included in the display panel DP as described with reference to FIG. 5A, and may include a light emitting element ED including a first electrode EL1, an emission layer EML, and a second electrode EL2.

Referring to FIGS. 7 and 8A to 8E, in the forming of the encapsulation layer (S200), the encapsulation layer TFE may be formed on the display element layer DP-ED to manufacture a preliminary display panel P-DP.

Referring to FIGS. 7, and 8A-8B, a substrate on which the display element layer DP-ED including the light emitting element ED is formed on the base layer BL may be prepared. Thereafter, a first inorganic layer IL1 may be formed on the substrate. The first inorganic layer IL1 may be formed through a deposition process. The first inorganic layer IL1 may be formed to cover the display element layer DP-ED including the light emitting element ED and the pixel defining film PDL, and to cover at least a portion of the circuit layer DP-CL. The first inorganic layer IL1 may be formed to have a step along the pixel opening OP defined in the pixel defining film PDL.

Referring to FIGS. 7 and 8C along with FIG. 5A, in the providing of a resin composition (S220), a resin composition RC may be provided on the first inorganic layer IL1 to form an organic layer OL. The organic layer OL may be a cured material formed by providing the resin composition RC on the first inorganic layer IL1 and then curing the first inorganic layer IL1. The resin composition RC may be applied onto the first inorganic layer IL1 overlapping the display region DA, and the resin composition RC may flow to at least a portion of the first inorganic layer IL1 overlapping the non-display region NDA.

The resin composition RC may be a fluid thermosetting resin composition or a photocurable resin composition. The resin composition RC may be formed through vapor deposition, printing, and/or slit coating, but the embodiment of the present disclosure is not limited thereto. In an embodiment, the organic layer OL may be formed through an ink-jet process.

For example, the resin composition RC may be provided on the first inorganic layer IL1 through an inkjet nozzle INJ. Thereafter, as the resin composition RC is cured, the organic layer OL may be formed from the resin composition RC. The resin composition RC of an embodiment may have a viscosity of about 5 cP to about 50 cP. The resin composition RC having a viscosity within the above range may exhibit excellent ejection stability. In addition, the resin composition RC may be smoothly ejected from a device such as the inkjet nozzle INJ when having the viscosity satisfying the above range, and the resin composition RC may be applied in a uniform (or substantially uniform) amount and in a uniform (or substantially uniform) thickness so as not to deviate from a member to which resin composition RC is supposed to be provided.

In an embodiment, the organic layer OL is formed from the resin composition RC having fluidity, and accordingly, when the organic layer OL is formed, reflow of the resin composition RC to a position adjacent to a position in which the organic layer OL is supposed to be formed may be identified. For example, the resin composition RC of an embodiment includes the near-infrared absorbing dye described above, and may thus allow the identification of the position of the edge EG of the organic layer OL. The organic layer OL is formed from the resin composition RC including a base resin and a near-infrared absorbing dye, and may thus allow the identification of an end point formed on the first inorganic layer IL1.

For example, in the resin composition RC for forming the organic layer OL, the near-infrared absorbing dye may be included in an amount in a range of greater than 0 wt % to 5 wt % or less with respect to a total weight of the resin composition RC. When the near-infrared absorbing dye is not included in the resin composition RC of an embodiment, the end point in which the organic layer OL is formed may be hardly identified. In addition, when the resin composition RC of an embodiment includes the near-infrared absorbing dye in an amount greater than the above range, the resin composition RC may not be well cured and the transmittance of the organic layer OL may decrease.

Referring to FIGS. 7 and 8D, in the identifying of an edge of an organic layer (S230), the edge EG of the organic layer OL formed on the first inorganic layer IL1 (FIG. 5A) may be identified. For example, the organic layer OL formed on the first inorganic layer IL1 is irradiated with near-infrared light NIR using a laser LZ, and then the position of forming the edge EG (FIG. 5A) of the organic layer OL may be identified with a near-infrared detector DN. For example, the near infrared light (NIR) irradiated onto the organic layer OL may be light in a wavelength range of about 750 nm or greater, or light in a wavelength range of about 750 nm to about 2500 nm. The laser LZ moves in the first direction DR1 and may be irradiated throughout the organic layer OL. However, the embodiment of the present disclosure is not limited thereto.

For example, the near-infrared detector ND may be a camera capable of detecting a near-infrared wavelength range. The near-infrared detector ND may be provided at a position that may capture images of the entire organic layer OL. However, the embodiment of the present disclosure is not limited thereto, and the near-infrared detector ND may be provided at a point where the edge EG (FIG. 5A) of the organic layer OL is expected to be formed. The near-infrared detector ND may detect the near-infrared absorbing dye included in the organic layer OL to identify the position of forming the organic layer OL. For example, in the identifying of an edge of an organic layer (S230), whether the organic layer OL is provided at a portion other than a desired position through the near-infrared absorbing dye included in the organic layer OL may be inspected.

The position of forming an edge EG of the organic layer OL may be different depending on the display panel DP and is not limited to any one embodiment. In an embodiment, the organic layer OL may be formed throughout the display element layer DP-ED, and an edge EG of the organic layer OL may be substantially aligned with an edge of the display element layer DP-ED on a cross section perpendicular (or substantially perpendicular) to the base layer BL. In addition, the organic layer OL may be on the display element layer DP-ED overlapping the display region DA, and may extend beyond the display region DA to a portion of the non-display region NDA. In this case, the edge EG of the organic layer OL may be substantially aligned with an edge of the fifth insulating layer 50 on which the first electrode EL1 is provided.

Referring to FIGS. 7 and 8E, in the forming of a second inorganic layer (S240), a preliminary display panel P-DP in which the organic layer OL is formed at a desired position is prepared, and a second inorganic layer IL2 may be formed on the organic layer OL of the preliminary display panel P-DP. The second inorganic layer IL2 may be formed through a deposition process. The second inorganic layer IL2 may cover the organic layer OL and may cover the first inorganic layer IL1 on which the organic layer OL is not formed.

In the method for manufacturing a display device of an embodiment, an organic layer of an encapsulation layer is formed with a resin composition including a near-infrared absorbing dye, and accordingly, in a step of identifying a position of forming the organic layer, reliability defects caused by reflow of the organic layer may be determined. In addition, in a display device of an embodiment, members for preventing or reducing the reflow of the organic layer may be minimized or reduced through components of the organic layer including a near-infrared absorbing dye to reduce a dead space, and thus the display device may have improved product quality.

A display device of an embodiment includes an organic layer in which a near-infrared absorbing dye is added to an encapsulation layer to prevent, minimize, or reduce inclusion of an organic layer reflow prevention member for reducing a dead space of a display panel, and may thus exhibit improved display quality.

According to a method for manufacturing a display device of an embodiment, reliability defects caused by reflow of an organic layer of an encapsulation layer may be identified in advance during a manufacturing process through a near-infrared absorbing dye included in the encapsulation layer, and thus a display device having improved reliability and product quality may be manufactured.

Although the subject matter of the present disclosure has been described with reference to example embodiments of the present disclosure, it will be understood that the present disclosure should not be limited to these example embodiments but various suitable changes and modifications may be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A display device comprising:
A base layer comprising a display region and a non-display region adjacent to the display region;
a light emitting element on the base layer and overlapping the display region; and
an encapsulation layer covering the light emitting element,
wherein the encapsulation layer comprises:
a first inorganic layer overlapping the display region and the non-display region;
a second inorganic layer on the first inorganic layer; and
an organic layer between the first inorganic layer and the second inorganic layer and comprising a near-infrared absorbing dye.

2. The display device of claim 1, wherein the organic layer comprises the near-infrared absorbing dye in an amount in range of greater than about 0 wt % to about 5 wt % or less.

3. The display device of claim 1, wherein the organic layer has a visible light transmittance of about 97% or greater.

4. The display device of claim 1, wherein the organic layer has a thickness in a range of about 0.3 μm to about 20 μm.

5. The display device of claim 1, wherein the near-infrared absorbing dye comprises at least one selected from the compounds of Compound Group 1 below:

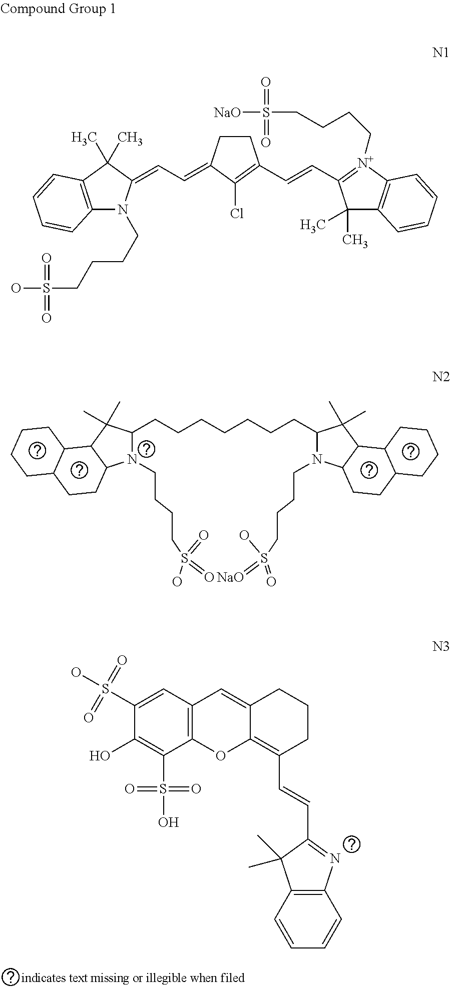

6. The display device of claim 1, wherein the organic layer is formed from a resin composition comprising the near-infrared absorbing dye and a base resin.

7. The display device of claim 6, wherein the base resin comprises at least one selected from an acryl-based resin, an epoxy-based resin, and a silicone-based resin.

8. The display device of claim 6, wherein the resin composition has a viscosity of about 5 cP to about 50 cP.

9. The display device of claim 1, further comprising a pixel defining film on the base layer and having a pixel opening and a recess portion defined therein,
wherein the pixel opening overlaps the display region, and the recess portion overlaps the non-display region,
the first inorganic layer is provided along a step between the pixel opening and the recess portion, and
the organic layer fills the pixel opening and the recess portion on the first inorganic layer.

10. The display device of claim 1, further comprising a dam portion overlapping the non-display region and spaced apart from the light emitting element and on the base layer.

11. The display device of claim 10, wherein the first inorganic layer covers the dam portion, and
the organic layer extends to the dam portion and is on one side of the dam portion adjacent to the display region on a cross section perpendicular to the base layer.

12. The display device of claim 1, wherein the non-display region has a width of about 1.5 μm or less on a plane parallel to the base layer.

13. A display device comprising:
a display element layer including a light emitting element;
an encapsulation layer on the display element layer and comprising a base resin and a near-infrared absorbing dye; and
a sensor layer on the encapsulation layer.

14. The display device of claim 13, wherein the encapsulation layer comprises at least one inorganic layer and at least one organic layer, and
the at least one organic layer comprises the base resin and the near-infrared absorbing dye.

15. The display device of claim 13, wherein the near-infrared absorbing dye absorbs light in a wavelength range of about 750 nm to about 2500 nm.

16. A method for manufacturing a display device, the method comprising:
forming a display element layer comprising a light emitting element on a base layer; and
forming an encapsulation layer on the display element layer,
wherein the forming of the encapsulation layer comprises:
forming a first inorganic layer on the display element layer;
providing a resin composition comprising a near-infrared absorbing dye on the first inorganic layer to form an organic layer;
identifying an edge of the organic layer; and
forming a second inorganic layer on the organic layer.

17. The method of claim 16, wherein the identifying of the edge of the organic layer comprises:
irradiating the organic layer with light in a wavelength range of about 750 nm to about 2500 nm; and
inspecting a position of forming the edge of the organic layer,
the position of forming the edge of the organic layer is distinguished by recognizing the near-infrared absorbing dye by utilizing a near-infrared detector.

18. The method of claim 16, wherein the first inorganic layer and the second inorganic layer are each formed through a deposition process.

19. The method of claim 16, wherein the organic layer is formed through an inkjet process.

20. The method of claim 16, wherein the near-infrared absorbing dye comprises at least one selected from the compounds of Compound Group 1 below: [chemical structure]
